(19) United States
(12) Patent Application Publication
(10) Pub. No.: US 2025/0089354 A1
(43) Pub. Date: Mar. 13, 2025

(54) SEMICONDUCTOR DEVICE

(71) Applicant: Sumitomo Electric Device Innovations, Inc., Yokohama-shi (JP)

(72) Inventors: Hiroshi SHIMURA, Yokohama-shi (JP); Norihiro YOSHIMURA, Yokohama-shi (JP)

(73) Assignee: Sumitomo Electric Device Innovations, Inc., Yokohama-shi (JP)

(21) Appl. No.: 18/826,825

(22) Filed: Sep. 6, 2024

(30) Foreign Application Priority Data
Sep. 8, 2023 (JP) 2023-146216

(51) Int. Cl. H01L 27/088; H01L 27/02; H01L 29/20; H01L 29/40; H01L 29/417

(52) U.S. Cl. CPC H10D 84/83; H10D 62/8503; H10D 64/111; H10D 64/258; H10D 89/10

(57) ABSTRACT

A semiconductor device includes a substrate, a compound semiconductor layer provided on the substrate, and a plurality of unit FETs arranged in a second direction intersecting a first direction, each of the unit FETs including a source electrode, a drain electrode, a gate electrode interposed between the source electrode and the drain electrode, and a field plate electrode. The plurality of unit FETs include a first unit FET, and a second unit FET close to an end of the plurality of unit FETs in the second direction. A first distance in the second direction between an end of the gate electrode closer to the drain electrode and an end of the field plate electrode closer to the drain electrode in the first unit FET is shorter than a second distance in the second direction therebetween in the second unit FET.

### CROSS REFERENCE TO RELATED APPLICATIONS

This application claims priority based on Japanese Patent Application No. 2023-146216 filed on Sep. 8, 2023, and the entire contents of the Japanese patent applications are incorporated herein by reference.

### FIELD

A certain aspect of the embodiments is related to a semiconductor device.

### BACKGROUND

It is known that a field plate is used in an FET (Field Effect Transistor) such as an HEMT (High Electron Mobility Transistor) having a compound semiconductor layer (for example, Patent Document 1: Japanese Laid-Open Patent Application No. 2019-102756, and Patent Document 2: Japanese Laid-Open Patent Application No. 2008-277604).

### SUMMARY

A semiconductor device according to the present disclosure includes: a substrate; a compound semiconductor layer provided on the substrate; and a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode; wherein the plurality of unit FETs include: a first unit FET; and a second unit FET closer to an end of the plurality of unit FETs in the second direction than the first unit FET; and wherein a first distance in the second direction between an end of the gate electrode closer to the drain electrode and an end of the field plate electrode closer to the drain electrode in the first unit FET is shorter than a second distance in the second direction between an end of the gate electrode closer to the drain electrode and an end of the field plate electrode closer to the drain electrode in the second unit FET.

A semiconductor device according to the present disclosure includes: a substrate; a compound semiconductor layer provided on the substrate; and a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode; wherein in at least one unit FET of the plurality of unit FETs, a first distance in the second direction between an end of the gate electrode closer to the drain electrode and an end of the field plate electrode closer to the drain electrode at a center of the at least one unit FET in the first direction is shorter than a second distance in the second direction between an end of the gate electrode closer to the drain electrode and an end of the field plate electrode closer to the drain electrode at an end of the at least one unit FET in the first direction.

### BRIEF DESCRIPTION OF DRAWINGS

FIG. 1 is a plan view of a semiconductor device according to a first embodiment.

FIG. 2 is a cross-sectional view taken along a line A-A in FIG. 1.

FIG. 3 is a plan view of unit FETs 30a, 30d and 30h in the first embodiment.

FIG. 4A is an A-A cross-sectional view of a unit FET 30a.

FIG. 4B is an A-A cross-sectional view of a unit FET 30d.

FIG. 4C is an A-A cross-sectional view of a unit FET 30h.

FIG. 5 is a diagram illustrating a length L1 and a distance L2 of each unit FET in the first embodiment.

FIG. 6 is a diagram illustrating a length L1 and a distance L2 of each unit FET in a first comparative example.

FIG. 7 is a diagram illustrating a length L1 and a distance L2 of each unit FET in a first modification of the first embodiment.

FIG. 8 is a plan view of unit FETs 30a, 30d and 30h in a second embodiment.

FIG. 9 is a diagram illustrating a length L1 and a distance L2 of each unit FET in a second embodiment.

FIG. 10 is a plan view of unit FETs 30a, 30d and 30h in a third embodiment.

FIG. 11 is a diagram illustrating a length L1 and a distance L2 in each unit FET in a third embodiment.

### DETAILED DESCRIPTION OF EMBODIMENTS

The use of the field plate suppresses the electric field concentration in a semiconductor layer between a gate electrode and a drain electrode. In addition, a drift phenomenon of a drain current such as current collapse can be suppressed. However, when the field plate is provided, the capacitance between the source and the drain increases, and the high-frequency characteristics deteriorate.

The present disclosure has been made in view of the above problems, and an object thereof is to suppress deterioration of high-frequency characteristics.

### DETAILS OF EMBODIMENTS OF THE PRESENT DISCLOSURE

First, the contents of the embodiments of this disclosure are listed and explained.

(1) A semiconductor device according to the present disclosure includes: a substrate; a compound semiconductor layer provided on the substrate; and a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode; wherein the plurality of unit FETs include: a first unit FET; and a second unit FET closer to an end of the plurality of unit FETs in the second direction than the first unit FET; and wherein a first distance in the second direction between an end of the gate electrode closer to the drain electrode and an end of the field plate electrode closer to the drain electrode in the first unit FET is shorter than a second distance in the second direction between an end of the gate electrode closer to the drain electrode and an end of the field plate electrode closer to the drain electrode in the second unit FET. This makes it possible to suppress deterioration of the high-frequency characteristics.

(2) In the above (1), a distance in the second direction between an end of the gate electrode closer to the drain electrode and an end of the field plate electrode closer to the drain electrode in a unit FET closest to a center of the plurality of unit FETs in the second direction may be the shortest in distances in the second direction between an end of the gate electrode closer to the drain electrode and an end of the field plate electrode closer to the drain electrode in the plurality of unit FETs. This improves the high-frequency characteristics.

(3) In the above (1) or (2), a distance in the second direction between an end of the gate electrode closer to the drain electrode and an end of the field plate electrode closer to the drain electrode in an unit FET closest to an end of the plurality of unit FETs in the second direction may be the longest in distances in the second direction between an end of the gate electrode closer to the drain electrode and an end of the field plate electrode closer to the drain electrode in the plurality of unit FETs. This improves the high-frequency characteristics.

(4) In any one of the above (1) to (3), the first distance at the center of the first unit FET in the first direction may be shorter than the first distance at the end of the first unit FET in the first direction. This improves the high-frequency characteristics.

(5) In any one of the above (1) to (4), the plurality of unit FETs may include a third unit FET provided between the first unit FET and the second unit FET in the second direction. A third distance between an end of the gate electrode closer to the drain electrode and an end of the field plate electrode closer to the drain electrode in the third unit FET in the second direction may be longer than the first distance and shorter than the second distance.

(6) In any one of the above (1) to (5), a first length of the field plate electrode in the second direction in the first unit FET may be shorter than a second length of the field plate electrode in the second direction in the second unit FET. This improves the high-frequency characteristics.

(7) A semiconductor device according to the present disclosure includes: a substrate; a compound semiconductor layer provided on the substrate; and a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode; wherein in at least one unit FET of the plurality of unit FETs, a first distance in the second direction between an end of the gate electrode closer to the drain electrode and an end of the field plate electrode closer to the drain electrode at a center of the at least one unit FET in the first direction is shorter than a second distance in the second direction between an end of the gate electrode closer to the drain electrode and an end of the field plate electrode closer to the drain electrode at an end of the at least one unit FET in the first direction. This improves the high-frequency characteristics.

(8) In the above (7), in a central portion included in the at least one unit FET, the central portion including the center in the first direction and having a constant width in the first direction, a distance in the second direction between an end of the gate electrode closer to the drain electrode and an end of the field plate electrode closer to the drain electrode may constant, and a distance in the second direction between an end of the gate electrode closer to the drain electrode and an end of the field plate electrode closer to the drain electrode gradually may increase from the central portion toward an end in the first direction. This improves the high-frequency characteristics.

(9) In any one of the above (1) to (8), in the plurality of unit FETs, the field plate electrode may be electrically short-circuited to the source electrode. This can suppress the drift of the drain current.

(10) In any one of the above (1) to (9), the compound semiconductor layer may be a nitride semiconductor layer. This makes it possible to further suppress the drift of the drain current.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

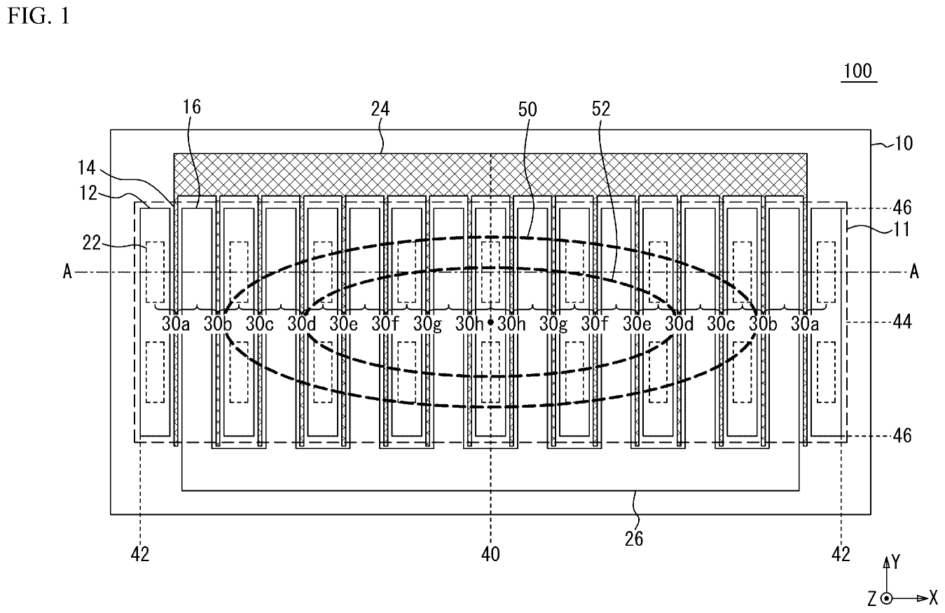

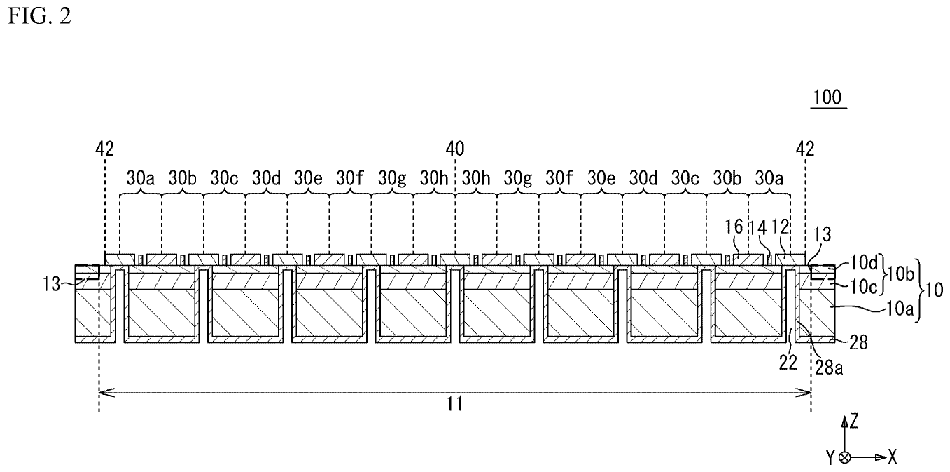

A first embodiment illustrates an example of FETs used in a high-frequency power amplifier. FIG. 1 is a plan view of a semiconductor device according to the first embodiment. FIG. 2 is a cross-sectional view taken along a line A-A in FIG. 1. An arrangement direction of a source electrode 12, a gate electrode 14 and a drain electrode 16 is defined as an X direction (a second direction intersecting the first direction), an extending direction is defined as a Y direction (the first direction), and a normal direction of a substrate 10 (that is, a direction perpendicular to the upper surface of the substrate 10) is defined as a Z direction. In FIGS. 1 and 2, a field plate is not illustrated.

As illustrated in FIGS. 1 and 2, in a semiconductor device 100, the substrate 10 includes a substrate 10a and a semiconductor layer 10b provided on the substrate 10a. The semiconductor layer 10b includes, for example, a channel layer 10c and a barrier layer 10d provided on the channel layer 10c. An active region 11 is formed in the substrate 10. The region other than the active region 11 is an inactive region 13 in which the semiconductor layer 10b is inactivated by ion implantation or the like. That is, the active region 11 is a region where the semiconductor layer 10b in the substrate 10 is activated, and the inactive region 13 is a region where the semiconductor layer 10b is deactivated.

The source electrode 12 (source finger), the gate electrode 14 (gate finger), and the drain electrode 16 (drain finger) are provided on the active region 11 so as to extend in the Y direction. Each of the source electrode 12, the gate electrode 14 and the drain electrode 16 has a substantially rectangular shape in plan view, and the long sides of the rectangular shape extend in the Y direction. The source electrode 12, the gate electrode 14 and the drain electrode 16 are arranged in the X direction.

The source electrodes 12 and the drain electrodes 16 are alternately provided in the X direction. The gate electrode 14 is interposed between one source electrode 12 and one drain electrode 16. The gate electrode 14, and the source electrode 12 and the drain electrode 16 interposing the gate electrode 14 form each of unit FETs 30a to 30h. The adjacent unit FETs 30a to 30h share the source electrode 12 or the drain electrode 16. The plurality of unit FETs 30a to 30h are arranged in the X direction. The unit FETs 30a to 30h are arranged in order from ends 42 to a center 40 in the X direction. The number of unit FETs can be set as appropriate. The ends 42 are ends in the X direction of the source electrodes 12 of the units FET 30a located at the outermost position in the X direction. The center 40 is the center of both ends 42 in the X direction.

A gate bus bar 24 and a drain bus bar 26 are provided on the inactive region 13 of the substrate 10. The gate bus bar 24 and the drain bus bar 26 extend in the X direction. The +Y ends of the plurality of gate electrodes 14 in the Y direction are connected to the gate bus bar 24. The −Y ends of the plurality of drain electrodes 16 in the Y direction are connected to the drain bus bar 26.

A via hole 22 is formed under the source electrode 12 and penetrates the substrate 10. A metal layer 28 is provided on the lower surface of the substrate 10. A reference potential such as a ground potential is supplied to the metal layer 28. A metal layer 28a is provided on the side and top (i.e., bottom) surfaces of the via hole 22. The metal layer 28a is the same metal layer as the metal layer 28 and they are formed at the same time. The source electrode 12 is electrically connected to the metal layer 28 through the via hole 22 and is short-circuited. As a result, the reference potential is supplied to the source electrode 12. The source electrode 12 may not have the via hole 22, but a source pad connected to the source electrode 12 may be provided on the inactive region 13, and the via hole may be formed in the source pad.

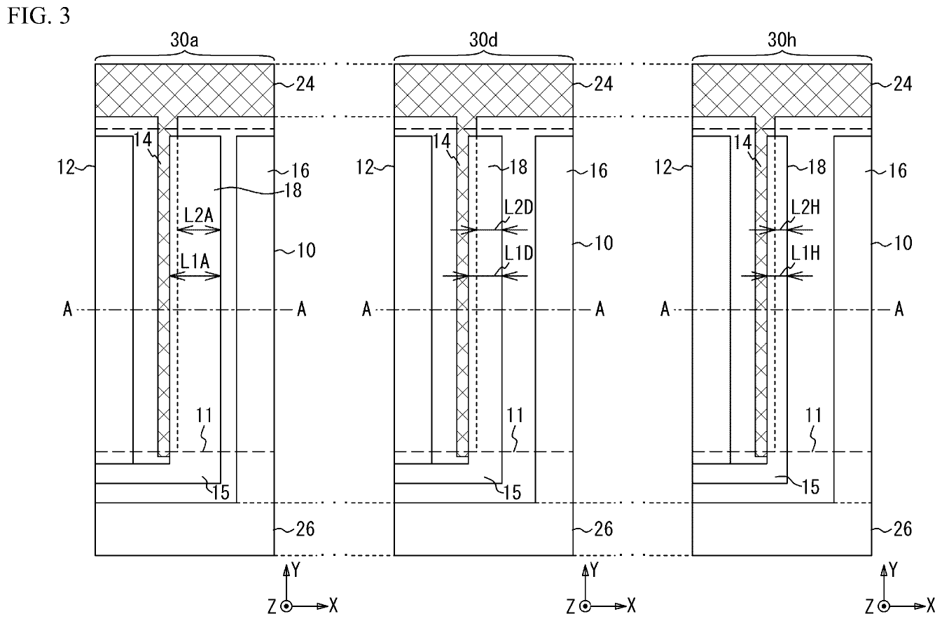

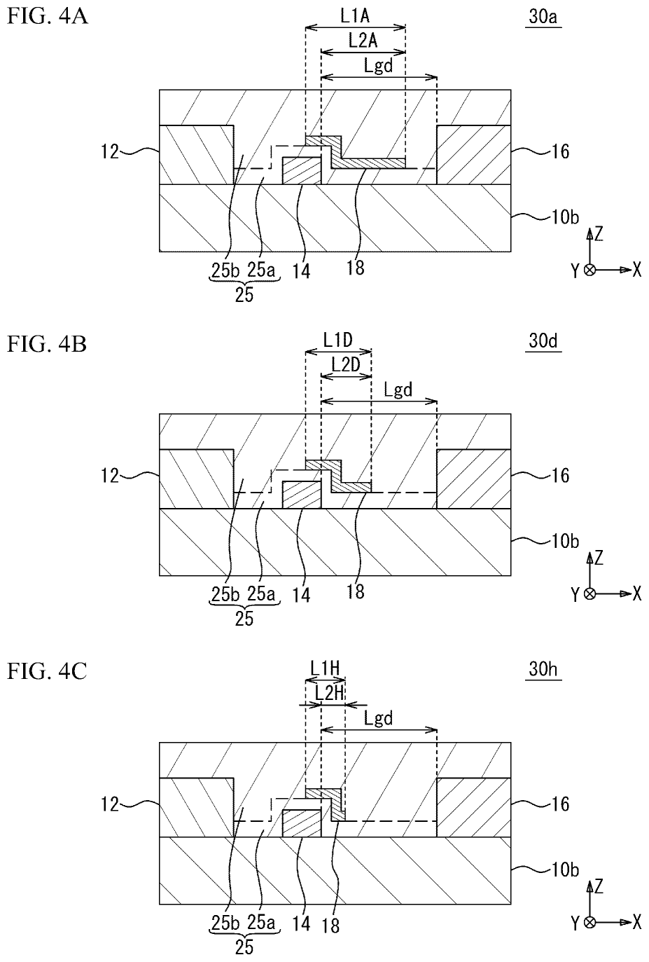

FIG. 3 is a plan view of the unit FETs 30a, 30d and 30h in the first embodiment. FIGS. 4A to 4C are A-A cross-sectional views of unit FETs 30a, 30d and 30h, respectively.

As illustrated in FIGS. 3 and 4A to 4C, a field plate electrode 18 extends in the X direction from above the gate electrode 14 to an intermediate position between the gate electrode 14 and the drain electrode 16, and is provided between the gate electrode 14 and the drain electrode 16 and above the semiconductor layer 10b with an insulating film 25a interposed between the semiconductor layer 10b and the field plate electrode 18. The field plate electrode 18 is electrically connected to the source electrode 12 by a wiring 15 outside the active region 11 and is short-circuited. The wiring 15 is formed of, for example, the same metal layer as the field plate electrode 18, and the wiring 15 and the source electrode 12 are in electrical contact with each other through an opening in the insulating film 25a. As a result, the reference potential is supplied to the field plate electrode 18. The field plate electrode 18 may pass above the gate electrode 14 in the active region 11 so as to interpose the insulating film 25a between the field plate electrode 18 and the gate electrode 14, and be electrically connected to the source electrodes 12. An insulating film 25b is provided on the source electrode 12, the drain electrode 16 and the field plate electrode 18. The insulating films 25a and 25b form an insulating film 25.

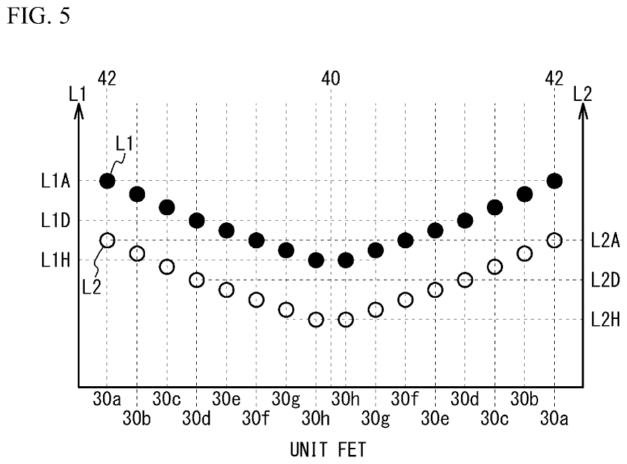

FIG. 5 is a diagram illustrating a length L1 and a distance L2 of each unit FET in the first embodiment. A horizontal axis of FIG. 5 indicates the unit FETs 30a to 30h arranged in the X direction, and a vertical axis indicates the length L1 and the distance L2 in the unit FETs 30a to 30h. The length L1 is a length of the field plate electrode 18 in the X direction. The distance L2 is a distance between an end of the gate electrode 14 closer to the drain electrode 16 in the X direction and an end of the field plate electrode 18 closer to the drain electrode 16 in the X direction.

As illustrated in FIGS. 3 and 4A to 4C, distances Lgd of the unit FETs 30a to 30h are substantially the same as each other to the extent of manufacturing error. The lengths L1 in the unit FETs 30a, 30d and 30h are L1A, L1D and L1H, respectively. The distances L2 in the unit FETs 30a, 30d and 30h are L2A, L2D and L2H, respectively. As illustrated in FIGS. 3 and 4A to 4C, L1A>L1D>L1H and L2A>L2D>L2H are satisfied. As illustrated in FIG. 5, the length L1 and the distance L2 become shorter from the ends 42 toward the center 40. In each of the unit FETs 30a to 30h, the length L1 is substantially constant in the Y direction to the extent of the manufacturing error, and the distance L2 is substantially constant in the Y direction to the extent of the manufacturing error.

The semiconductor layer 10b is a compound semiconductor layer, for example, a nitride semiconductor layer or an arsenide semiconductor layer. When the semiconductor layer 10b is the nitride semiconductor layer, the substrate 10a is, for example, a silicon carbide (SiC) substrate, a sapphire substrate, a gallium nitride (GaN) substrate, or a diamond substrate. The semiconductor layer 10b includes one or more nitride semiconductor layers such as gallium nitride, aluminum gallium nitride (AlGaN), or indium gallium nitride (InGaN). When the semiconductor device is a GaN HEMT, the channel layer 10c is, for example, a gallium nitride layer, and the barrier layer 10d is, for example, an aluminum gallium nitride layer.

When the semiconductor layer 10b is the arsenide semiconductor layer, the substrate 10a is, for example, a gallium arsenide (GaAs) substrate. The semiconductor layer 10b includes one or more arsenide semiconductor layers such as gallium arsenide, aluminum gallium arsenide (AlGaAs), or indium gallium arsenide (InGaAs).

The source electrode 12 and the drain electrode 16 are, for example, a metal film such as an adhesion film (for example, a titanium film) provided on the substrate 10 and an aluminum film provided on the adhesion film. A low resistance film such as gold may be formed on the aluminum film. The gate electrode 14 is, for example, a metal film such as an adhesion film (for example, a nickel film) provided on the substrate 10 and a gold film provided on the adhesion film. The field plate electrode 18 is a metal film such as an adhesion film (for example, a nickel film or a titanium film) provided on the insulating film 25a and a low resistance film (for example, an aluminum film or a gold film) provided on the adhesion film. The metal layers 28 and 28a are, for example, gold layers.

The insulating film 25a is an inorganic insulating film such as a silicon nitride layer, a silicon oxide layer, or a silicon oxynitride layer, and is, for example, a silicon nitride layer. The insulating film 25b is, for example, an inorganic insulating film such as a silicon nitride layer, a silicon oxide layer, or a silicon oxynitride layer, or an organic insulating film such as a polyimide layer.

### First Comparative Example

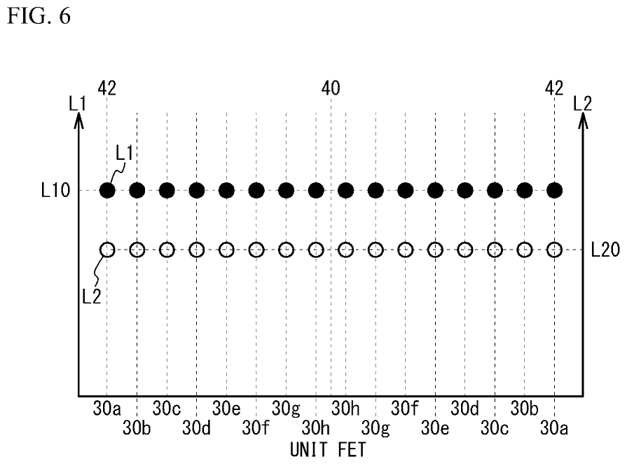

FIG. 6 is a diagram illustrating the length L1 and the distance L2 of each unit FET in a first comparative example. As illustrated in FIG. 6, in the first comparative example, the length L1 of the unit FETs 30a to 30h is a length L10, which is substantially constant to the extent of the manufacturing error. The distance L2 between the unit FETs 30a and 30h is a distance L20, which is substantially constant to the extent of the manufacturing error.

The field plate electrode 18 is provided between the gate electrode 14 and the drain electrode 16 and above the semiconductor layer 10b with the insulating film 25a interposed between the field plate electrode 18 and the semiconductor layer 10b, whereby electric field concentration in the semiconductor layer 10b can be suppressed. When the electric field in the semiconductor layer 10b between the gate electrodes 14 and the drain electrodes 16 is increased, a drain idle current (Idq) drift or a drift of a drain current called a current collapse phenomenon is likely to occur. The mechanism of the drift of the drain current will be described. The high electric field causes electrons to have high energy and to be captured by traps in the semiconductor layer 10b. This reduces the drain current. The electrons captured in the traps are released with time. Therefore, when the electric field between the gate electrode 14 and the drain electrode 16 becomes low, the drain current recovers with time. In this way, the drift of the drain current occurs.

For example, when a semiconductor device is used in an amplifier circuit, if the drift of the drain current occurs, the output characteristic of the amplifier circuit is affected by the immediately preceding output and changes. This complicates the processing of a distortion compensation circuit of the amplifier circuit, and makes it difficult to compensate for the distortion. Such a drift of the drain current is a problem that occurs in an FET using a compound semiconductor layer as the semiconductor layer 10b, and is particularly likely to occur in a case where a nitride semiconductor layer is used as the semiconductor layer 10b.

When the length of the field plate electrode 18 between the gate electrode 14 and the drain electrode 16 (i.e., the distance L2) is increased, the electric field in the semiconductor layer 10b is relaxed, and the number of electrons captured by the trap is reduced. This reduces the drift of the drain current. However, when the distance L2 is increased, the distance between the field plate electrode 18 and the drain electrode 16 is reduced, and the source-drain capacitance Cds is increased. This deteriorates the high-frequency characteristics of the semiconductor device.

As described above, in a first comparative example, when the length L1 and the distance L2 are increased, the drift of the drain current is suppressed, but the source-drain capacitance Cds increases, and the high-frequency characteristics deteriorate. When the length L1 and the distance L2 are shortened, the source-drain capacitance Cds reduces and the high-frequency characteristics are improved, but the drift of the drain current is increased.

In order to reduce the source-drain capacitance Cds, it is also conceivable to increase the distance Lgd between the gate electrode 14 and the drain electrode 16. However, when the distance Lgd is increased, the drain resistance is increased.

### Operation of First Embodiment

Broken lines 50 and 52 in FIG. 1 are isotherms illustrating temperature distributions when the semiconductor device 100 is operated. The broken line 52 is higher in temperature than the broken line 50. In the unit FET 30a to the 30h, the unit FET 30h closest to the center 40 has the highest temperature, and the unit FETs 30a closest to the ends 42 of the unit FETs 30a to 30h in the X direction have the lowest temperature. The temperatures of the unit FETs 30b to 30g decrease from the center 40 toward the ends 42.

In the drift of the drain current drift, the time constant of the release of the electrons from the traps is faster as the temperature is higher. Therefore, when the temperature is increased, the drift of the drain current is relaxed. As a result, the drift of the drain current is small in the unit FET 30h close to the center 40, and the drift of the drain current is large in the unit FETs 30a close to the ends 42.

In the unit FET 30h (first unit FET) having a high temperature, even if the distance L2H (first distance) is shortened, the drift of the drain current is small and can be within an allowable range of the drift of the drain current. On the other hand, in the unit FET 30a (second unit FET) having a low temperature, when the distance L2A (second distance) is shortened, the drift of the drain current becomes large, and exceeds the allowable range of the drift of the drain current. Therefore, the distance L2H is made shorter than the distance L2A. As a result, in the unit FET 30h, the drift of the drain current can be kept within the allowable range, and the source-drain capacitance Cds can be reduced. On the other hand, in the unit FET 30a, although the source-drain capacitance Cds is large, the drift of the drain current can be made within the allowable range. Thus, in both the first embodiment and the comparative example, the drift of the drain current is within the allowable range, and in the first embodiment, as a whole semiconductor device, the source-drain capacitance Cds can be suppressed and the high-frequency characteristics can be improved as compared with the first comparative example.

In addition, the unit FET 30d (third unit FET) is provided between the unit FETs 30h and 30a in the X direction. The distance L2D (third distance) of the unit FET 30d is longer than the distance L2H and shorter than the distance L2A. Thus, in the unit FET 30d, the drift of the drain current can be kept within the allowable range, and the source-drain capacitance Cds can be reduced. Therefore, as the whole semiconductor device, the drift of the drain current can be made within the allowable range, the source-drain capacitance Cds can be suppressed, and the high-frequency characteristics can be improved.

The source-drain capacitance Cds is affected not only by the distance between the field plate electrode 18 and the drain electrode 16 but also by the length L1 of the field plate electrode 18 in the X direction. That is, as the length L1 increases, the source-drain capacitance Cds increases. On the other hand, when the length L1 increases, the distance L2 increases, and the drift of the drain current is suppressed.

Therefore, the length L1H (first length) of the field plate electrode 18 in the X direction in the unit FET 30h is shorter than the length L1A (second length) of the field plate electrode 18 in the X direction in the unit FET 30a. This makes it possible to keep the drift of the drain current within the allowable range, to suppress the source-drain capacitance Cds and to improve the high-frequency characteristics as the whole semiconductor device.

The length L1D (third length) of the field plate electrode 18 in the X direction in the unit FET 30d is shorter than the length L1A and longer than the length L1H. This makes it possible to keep the drift of the drain current within the allowable range, to suppress the source-drain capacitance Cds and to improve the high-frequency characteristics as the whole semiconductor device.

In order to suppress the source-drain capacitance Cds, the distance L2H of the unit FET 30h closest to the center 40 can be set to 0.9 times or less, 0.8 times or less, or 0.7 times or less the distance L2A of the unit FET 30a closest to the end 42. The length L1H of the unit FET 30h closest to the center 40 can be 0.9 times or less, 0.8 times or less, or 0.7 times or less the length L1A of the unit FET 30a closest to the end 42. The distance L2H and the length L1H of the unit FET 30h may be 0. That is, the unit FET 30h may not include the field plate electrode 18.

### First Modification of First Embodiment

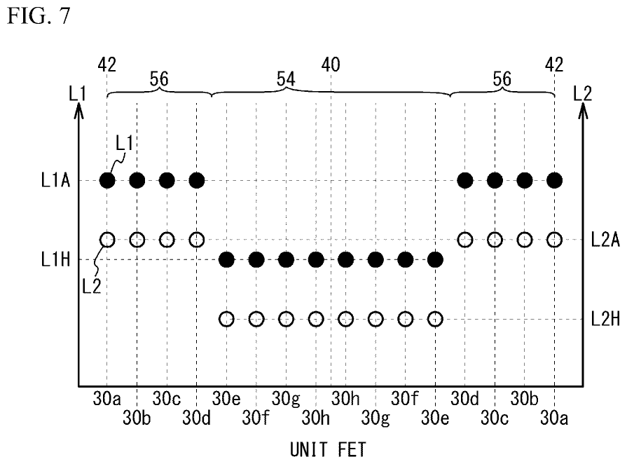

FIG. 7 is a diagram illustrating the length L1 and the distance L2 of each unit FET in the first modification of the first embodiment. As illustrated in FIG. 7, for example, the lengths L1H of the unit FETs 30e to 30h in a group 54 including the center 40 are substantially the same as each other to the extent of the manufacturing error, and the distances L2H thereof are substantially the same as each other the extent of the manufacturing error. The lengths L1A of the unit FETs 30a to 30d in a group 56 including the ends 42 are substantially the same as each other to the extent of the manufacturing error, and the distances L2A thereof are substantially the same as each other to the extent of the manufacturing error. As in the first modification of the first embodiment, the unit FETs 30a to 30h may be divided into the plurality of groups 54 and 56, and the lengths L1 may be substantially the same as each other and the distances L2 may be substantially the same as each other in each of the groups 54 and 56. The number of groups 54 and 56 may be three or more.

A unit FET having the highest temperature in the unit FETs 30a to 30h is the unit FET 30h closest to the center 40. Therefore, as in the first embodiment and the first modification thereof, the distance L2H of the unit FET 30h closest to the center 40 in the unit FETs 30a to 30h can be made the shortest in the distances L2 of the unit FETs 30a to 30h. This improves the high-frequency characteristics.

A unit FET having the lowest temperature in the unit FETs 30a to 30h is the unit FET 30a closest to the end 42. Therefore, as in the first embodiment and the first modification thereof, the distance L2A of the unit FET 30a closest to the end 42 in the unit FETs 30a to 30h can be made the longest in the distances L2 of the unit FETs 30a to 30h. This improves the high-frequency characteristics.

As in the first embodiment, the length L1 may be gradually reduced and the distance L2 may be gradually reduced from the ends 42 toward the center 40. As illustrated in FIG. 5, the length L1 and the distance L2 may be changed linearly with respect to the horizontal axis along which the unit FETs are arranged. The length L1 and the distance L2 may be changed in a curved line with respect to the horizontal axis along which the unit FETs are arranged. As in the first modification of the first embodiment, the length L1 may be shortened stepwise from the end 42 toward the center 40, and the distance L2 may be shortened stepwise from the end 42 toward the center 40. The length L1 and the distance L2 may be symmetrical in the X direction with respect to the center 40 or asymmetrical in the X direction with respect to the center 40.

### Second Embodiment

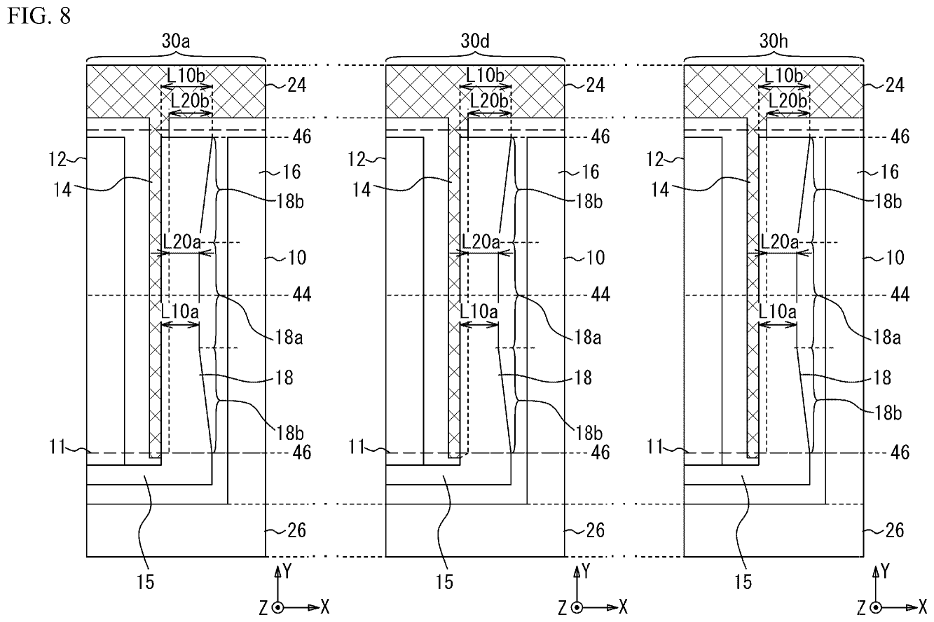

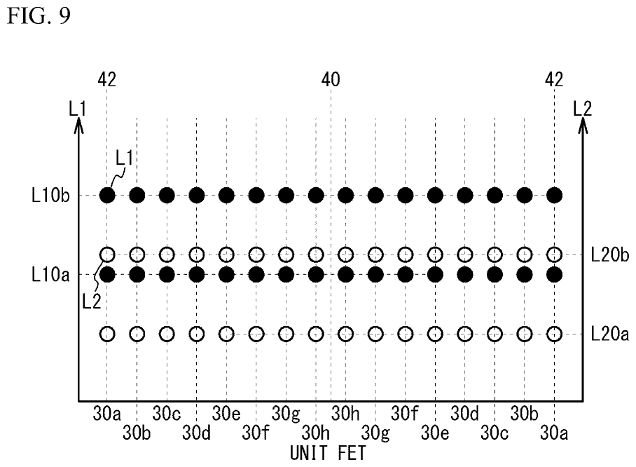

FIG. 8 is a plan view of the unit FETs 30a, 30d, and 30h in the second embodiment. FIG. 9 is a diagram illustrating the length L1 and the distance L2 of each unit FET in the second embodiment.

As illustrated in FIG. 8, in the unit FETs 30a to 30h, the center and the ends in the Y direction are respectively designated by 44 and 46. The end 46 on the positive side in the Y direction is an end of the drain electrode 16, and the end 46 on the negative side in the Y direction is an end of the source electrode 12 or the active region 11. The center 44 is a center in the Y direction of both ends 46.

A region including the center 44 of the field plate electrode 18 in the Y direction is defined as a central portion 18a. Regions including the ends 46 of the field plate electrode 18 in the Y direction is referred to as end portions 18b. As illustrated in FIG. 9, in the unit FETs 30a to 30h, a length L10b at the ends 46 is longer than a length L10a at the center 44. In the unit FETs 30a to 30h, a distance L20b at the ends 46 is longer than a distance L20a at the center 44. The lengths L10a of the unit FETs 30a to 30h are substantially the same as each other to the extent of the manufacturing error, the lengths L10b of the unit FETs 30a to 30h are substantially the same as each other to the extent of the manufacturing error, the distances L20a of the unit FETs 30a to 30h are substantially the same as each other to the extent of the manufacturing error, and the distances L20b of the unit FETs 30a to 30h are substantially the same as each other to the extent of the manufacturing error.

As illustrated in FIG. 8, in the range of the central portion 18a, the lengths L10a are substantially the same as each other to the extent of the manufacturing error, and the distances L20a are substantially the same as each other to the extent of the manufacturing error. At the end portions 18b between the central portion 18a and the ends 46, the length L10 gradually increases from the central portion 18a toward the ends 46, and the distance L20 gradually increases from the central portion 18a toward the ends 46. The other configurations are the same as those of the first embodiment, and the description thereof is omitted.

### Operation of Second Embodiment

As illustrated in FIG. 1, when the semiconductor device 100 is operated, the temperature at the center 44 in the Y direction is the highest and the temperature at the ends 46 in the Y direction is the lowest in the unit FETs 30a to 30h. The temperature decreases from the center 44 toward the ends 46.

Therefore, in at least one of the unit FETs 30a to 30h, the distance L20a (first distance) at the center 44 in the Y direction is made shorter than the distance L20b (second distance) at the ends 46 in the Y direction. The length L10a at the center 44 is made shorter than the length L10b at the ends 46. Thus, since the distance L20a is short at the center 44 where the temperature is high, the drift of the drain current is within the allowable range, and the source-drain capacitance Cds can be reduced. Since the distance L20b is long at the ends 46, the drift of the drain current can be within the allowable range even if the temperature is low. This makes it possible to keep the drift of the drain current within the allowable range, to suppress the source-drain capacitance Cds and to improve the high-frequency characteristics as the whole semiconductor device.

In the unit FETs 30a to 30h, the unit FET closer to the center 40 tends to have a larger temperature distribution in the Y direction. Therefore, the distance L20a at the center 44 of at least the unit FET 30h in the unit FETs 30a to 30h can be made shorter than the distance L20b at the ends 46 of the unit FET 30h.

In the unit FET 30h, a difference between distances L20b and L20a (i.e., L20b-L20a) can be 0.05 times or more, 0.1 times or more, or 0.2 times or more the distance L20b. A difference between distances L10b and L10a (i.e., L10b-L10a) can be 0.05 times or more, 0.1 times or more, or 0.2 times or more the length L10b.

### Third Embodiment

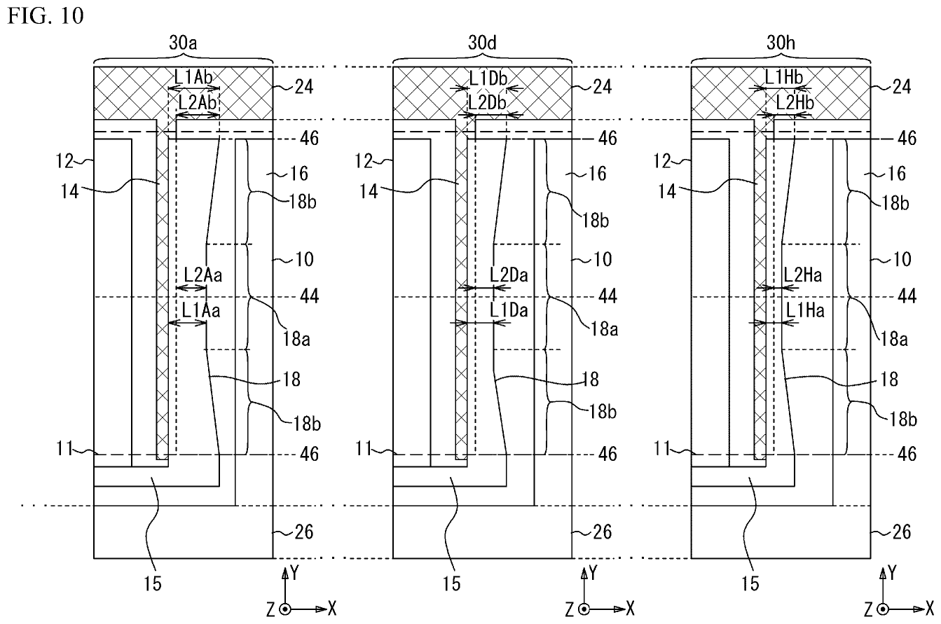

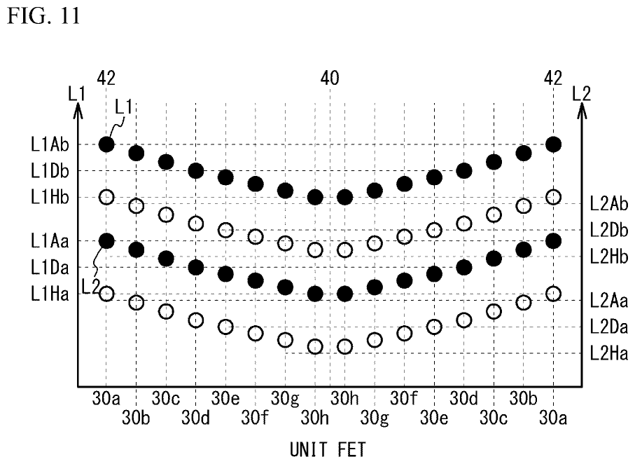

FIG. 10 is a plan view of the unit FETs 30a, 30d and 30h in a third embodiment. FIG. 11 is a diagram illustrating the length L1 and the distance L2 of each unit FET in the third embodiment.

As illustrated in FIG. 10, the lengths L1 at the center 44 of the unit FETs 30a, 30d, and 30h in the Y direction are L1Aa, L1Da, and L1Ha, respectively. The distances L2 at the center 44 of the unit FETs 30a, 30d, and 30h in the Y direction are L2Aa, L2 Da, and L2Ha, respectively. The lengths L1 at the ends 46 of the unit FETs 30a, 30d and 30h in the Y direction are L1Ab, L1Db and L1Hb, respectively. The distances L2 at the ends 46 of the unit FETs 30a, 30d and 30h in the Y direction are L2Ab, L2Db and L2Hb, respectively.

L1Aa<L1Ab, L2Aa<L2Ab, L1Da<L1Db, L2Da<L2Db, L1Ha<L1Hb, and L2Ha<L2Hb, and L1Aa>L1Da>L1Ha, L1Ab>L1Db>L1Hb, L2Aa>L2Da>L2Ha, and L2Ab>L2Db>L2Hb are satisfied.

As illustrated in FIG. 11, the length L1 at the ends 46 (see FIG. 10) is longer than the length L1 at the center 44 (see FIG. 10) in the unit FETs 30a to 30h. In the unit FETs 30a to 30h, the distance L2 at the ends 46 is longer than the distance L2 at the center 44. The length L1 and the distance L2 at the center 44 become shorter from the ends 42 toward the center 40. The length L1 and the distance L2 at the ends 46 become shorter from the ends 42 toward the center 40. The other configurations are the same as those of the second embodiment, and the description thereof is omitted.

### Operation of Third Embodiment

As illustrated in FIG. 1, when the semiconductor device 100 is operated, the temperatures of the unit FETs 30a to 30h are highest at the center 40 and the center 44, and the temperatures decrease from the center 40 toward the ends 42 and from the center 44 toward the ends 46.

Therefore, the distances L2Ha and L2Hb in the unit FET 30h are made shorter than the distances L2Aa and L2Ab in the unit FET 30a, respectively, and the distance L2Ha in the unit FET 30h is made shorter than the distance L2Hb. Thereby, since the distance L2Ha is short at the centers 40 and 44 where the temperature is high, the drift of the drain current is within the allowable range, and the source-drain capacitance Cds can be reduced. Since the distances L2Aa are long at the ends 42 and 46, the drift of the drain current can be within the allowable range even at a low temperature. This makes it possible to keep the drift of the drain current within the allowable range, to suppress the source-drain capacitance Cds and to improve the high-frequency characteristics as the whole semiconductor device. Also in the unit FET 30a, the distance L2Aa may be made shorter than the distance L2Ab.

The unit FET closer to the center 40 in the unit FETs 30a to 30h tends to have a larger temperature distribution in the Y direction. Therefore, the distance L1Ha at the center 44 of at least the unit FET 30h in the unit FETs 30a to 30h can be made shorter than the distance L1Hb at the ends 46 of the unit FET 30h.

The lengths L1Ha and L1Hb in the unit FET 30h may be shorter than the lengths L1Aa and L1Ab in the unit FET 30a, respectively, and the length L1Ha may be shorter than the length L1Hb in the unit FET 30h. In the unit FET 30a, the length L1Aa may be shorter than the length L1Ab.

In FIG. 1, the temperature of the unit FETs 30a to 30h is relatively constant in the vicinity of the central portion in the Y direction, and the temperature drops sharply as the unit FETs approach the ends 46. Accordingly, the length L1 and the distance L2 at the end portions 18b can be gradually increased from the central portion 18a toward the ends 46, while the length L1 and the distance L2 at the central portion 18a having a constant width in the Y direction and including the center 40 are constant. The width of the central portion 18a in the Y direction is, for example, 0.1 times or more and 0.9 times or less, or 0.3 times or more and 0.6 times or less the gate width of the unit FETs 30a to 30h.

In the second and third embodiments, the length L1 and the distance L2 at the end portions 18b are linearly increased from the central portion 18a toward the ends 46, but may be increased in a curved manner. The length L1 of the end portion 18b may be constant at any position in the Y direction, and the distance L2 may be constant at any position in the Y direction. The length L1 and the distance L2 in the Y direction may be gradually increased from the center 44 toward the ends 46 without providing the central portion 18a having the constant length L1 and the constant distance L2. The length L1 and the distance L2 may be symmetrical in the Y direction with respect to the center 44 or asymmetrical in the Y direction with respect to the center 44.

In the first to the third embodiment, in the unit FETs 30a to 30h, the field plate electrode 18 is electrically shorted to the source electrode 12. This makes it possible to further suppress the electric field concentration in the semiconductor layer 10b between the gate electrode 14 and the drain electrode 16.

In the unit FETs 30a to 30h, the field plate electrode 18 may not be provided above the gate electrode 14. The field plate electrode 18 is provided above the gate electrode 14 with the insulating film 25a interposed therebetween, whereby a parasitic capacitance between the gate electrode 14 and the drain electrode 16 can be suppressed.

The drift of the drain current is likely to occur when the semiconductor layer 10b is the nitride semiconductor layer. Accordingly, when the semiconductor layer 10b is the nitride semiconductor layer, the length L1 and the distance L2 can be made different from each other as in the first to the third embodiments.

The drift of the drain current is likely to occur when the semiconductor layer 10b includes a gallium nitride channel layer and an aluminum gallium nitride barrier layer. Accordingly, when the semiconductor layer 10b includes the gallium nitride channel layer and the aluminum gallium nitride barrier layer, the length L1 and the distance L2 can be made different from each other as in the first to the third embodiments.

The embodiments disclosed here should be considered as illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
a compound semiconductor layer provided on the substrate; and
a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode;
wherein the plurality of unit FETs include:
a first unit FET; and
a second unit FET closer to an end of the plurality of unit FETs in the second direction than the first unit FET; and
wherein a first distance in the second direction between an end of the gate electrode closer to the drain electrode and an end of the field plate electrode closer to the drain electrode in the first unit FET is shorter than a second distance in the second direction between an end of the gate electrode closer to the drain electrode and an end of the field plate electrode closer to the drain electrode in the second unit FET.

2. The semiconductor device according to claim 1, wherein
a distance in the second direction between an end of the gate electrode closer to the drain electrode and an end of the field plate electrode closer to the drain electrode in a unit FET closest to a center of the plurality of unit FETs in the second direction is the shortest in distances in the second direction between an end of the gate electrode closer to the drain electrode and an end of the field plate electrode closer to the drain electrode in the plurality of unit FETs.

3. The semiconductor device according to claim 1, wherein
a distance in the second direction between an end of the gate electrode closer to the drain electrode and an end of the field plate electrode closer to the drain electrode in an unit FET closest to an end of the plurality of unit FETs in the second direction is the longest in distances in the second direction between an end of the gate electrode closer to the drain electrode and an end of the field plate electrode closer to the drain electrode in the plurality of unit FETs.

4. The semiconductor device according to claim 1, wherein
the first distance at the center of the first unit FET in the first direction is shorter than the first distance at the end of the first unit FET in the first direction.

5. The semiconductor device according to claim 1, wherein
the plurality of unit FETs include a third unit FET provided between the first unit FET and the second unit FET in the second direction,
a third distance between an end of the gate electrode closer to the drain electrode and an end of the field plate electrode closer to the drain electrode in the third unit FET in the second direction is longer than the first distance and shorter than the second distance.

6. The semiconductor device according to claim 1, wherein
a first length of the field plate electrode in the second direction in the first unit FET is shorter than a second length of the field plate electrode in the second direction in the second unit FET.

7. A semiconductor device comprising:
a substrate;
a compound semiconductor layer provided on the substrate; and
a plurality of unit FETs arranged in a second direction intersecting a first direction, each of the unit FETs including: a source electrode provided on the compound semiconductor layer and extending in the first direction; a drain electrode provided on the compound semiconductor layer and extending in the first direction; a gate electrode provided on the compound semiconductor layer and extending in the first direction and interposed between the source electrode and the drain electrode; and a field plate electrode provided between the gate electrode and the drain electrode and above the compound semiconductor layer with an insulating film interposed between the compound semiconductor layer and the field plate electrode;
wherein in at least one unit FET of the plurality of unit FETs, a first distance in the second direction between an end of the gate electrode closer to the drain electrode and an end of the field plate electrode closer to the drain electrode at a center of the at least one unit FET in the first direction is shorter than a second distance in the second direction between an end of the gate electrode closer to the drain electrode and an end of the field plate electrode closer to the drain electrode at an end of the at least one unit FET in the first direction.

8. The semiconductor device according to claim 7, wherein
in a central portion included in the at least one unit FET, the central portion including the center in the first direction and having a constant width in the first direction, a distance in the second direction between an end of the gate electrode closer to the drain electrode and an end of the field plate electrode closer to the drain electrode is constant, and a distance in the second direction between an end of the gate electrode closer to the drain electrode and an end of the field plate electrode closer to the drain electrode gradually increases from the central portion toward an end in the first direction.

9. The semiconductor device according to claim 1, wherein
in the plurality of unit FETs, the field plate electrode is electrically short-circuited to the source electrode.

10. The semiconductor device according to claim 7, wherein
in the plurality of unit FETs, the field plate electrode is electrically short-circuited to the source electrode.

11. The semiconductor device according to claim 1, wherein
the compound semiconductor layer is a nitride semiconductor layer.

12. The semiconductor device according to claim 7, wherein
the compound semiconductor layer is a nitride semiconductor layer.
